(19) United States
(12) Patent Application Publication
(10) Pub. No.: US 2013/0009183 A1
(43) Pub. Date: Jan. 10, 2013

(54) REFLECTIVE CIRCUIT BOARD FOR LED BACKLIGHT

(76) Inventor: Chang HAN, Pleasanton, CA (US)

(21) Appl. No.: 13/179,443

(22) Filed: Jul. 8, 2011

(51) Int. Cl. H01L 33/60; H01L 33/52

(52) U.S. Cl. 257/98; 438/27; 257/E33.059; 257/E33.072

(57) ABSTRACT

An LED device with improved LED efficiency is presented. A top surface of a circuit board carrying the LED die is covered with a reflective layer. The reflective surface on top of the circuit board allows the light reflected off a surface of a waveguide to be recycled by being redirected back to the waveguide.

### FIELD

The example embodiments of the present invention pertain generally to devices comprising light-emitting diodes (LEDs), including devices comprising surface-mounted LEDs.

### BACKGROUND

Light-emitting diodes (LEDs) are widely used as a semiconductor lighting source. One of the methods of constructing an electronic circuit using an LED is surface-mount technology, also known as chip-on-board (COB) technology, in which the LED is mounted directly on a printed circuit board (PCB). In COB devices, an LED die is supplied without a package and attached directly to a circuit board. The LED die is then wire bonded and protected from mechanical damage and contamination by an epoxy “glob-top.” The light emitted by the LED die is guided from the LED die to the desired location by an optical waveguide such as an optical fiber or a rectangular waveguide.

When the light emitted by the LED die reaches the surface of the waveguide a portion of the light is reflected back towards the PCB and absorbed or scattered by the top surface of the PCB, which may cause a substantial brightness loss by the device.

FIG. 1 depicts a prior-art device with a typical attachment of an LED die 1 to a substrate 3. A dielectric layer 5 is attached on top of the substrate 3. The dielectric layer 5 has an opening 7 to form a pocket 9 in which the LED die 1 is placed. The pocket 9 is formed by the walls 11 of the opening 7 and the top surface 13 of the substrate 3. Electrode pads and conductive leads 15 are formed over the dielectric layer 5. The LED die 1 is connected to these electrode pads and leads by conductive leads such as wires 17. Waveguide 19 is positioned over the substrate 3. The light 21 emitted by the LED die 1 travels from the LED die 1 to the surface of the waveguide 19. A portion 23 of the light 21 travels through the surface 25 of the waveguide 19. However, a significant portion 27 of the light 21 is reflected by the surface 25 of the waveguide 19 and travels towards the substrate 3. The dielectric layer 5 and the electrode pads and wires 17 covering the substrate 3 have very low reflectivity and mostly absorb and scatter the portion 27 of the light reflected off the surface 25 of the waveguide 19.

FIG. 2 depicts another prior-art device whose design also suffers from the loss of brightness. In this instance, the LED die 1 is an ultra-violet (UV) LED die positioned on the bottom of the pocket 9 formed on the top surface 13 of the substrate 3. After the die 31 is placed in the pocket 9, the pocket 9 is filled with phosphor 29. When the UV light emitted by the UV LED die 31 passes through the phosphor 19, the phosphor absorbs the UV light and emits light 21 of the visible spectrum, white light. As in the device of FIG. 1, a larger portion 27 of the light 21 is reflected off the surface 25 of the waveguide 19 and scattered and absorbed by the circuit board.

### BRIEF SUMMARY

In view of the foregoing, example embodiments of the present invention provide LED devices with improved LED efficiency and methods for making the same. The LED devices of example embodiments of the present invention have a reflective layer over at least a portion of the circuit board on which the LED die is positioned. The light emitted by the LED and reflected off the surface of the waveguide are redirected back to the waveguide by the top surface of the reflective layer covering the circuit board. In some example embodiments, the top surface of the reflective layer is covered with a reflective coating such as foil or film. In other example embodiments, the top surface of the circuit board is covered with a reflective coating. In yet another example embodiment, the top surface of the circuit board is polished. Also, different combinations of covering with a reflective layer, depositing a reflective coating or polishing are also described in this application. In some example embodiments of the present invention, multiple LED devices are formed on the same substrate.

### BRIEF DESCRIPTION OF THE SEVERAL VIEWS OF THE DRAWING(S)

Having thus described the example embodiments of the present invention in general terms, reference will now be made to the accompanying drawings, which are not necessarily drawn to scale, and wherein:

FIG. 1 depicts a cross-section diagram of a prior-art device.

FIG. 2 depicts a cross-section diagram of another prior-art device.

FIGS. 3a-d depict cross-sectional diagrams of the devices of example embodiments of the present invention.

FIGS. 4a-d depict cross-sectional diagrams of the devices of other example embodiments of the present invention with phosphor.

FIGS. 5 and 5A depict cross-sectional diagrams of the devices of other example embodiments of the present invention with a waveguide.

FIGS. 6a-d depict cross-sectional diagrams of the devices of yet other example embodiments of the present invention with a protective layer.

FIGS. 7-11 depict steps in the assembly of the device of an example embodiment of the present invention.

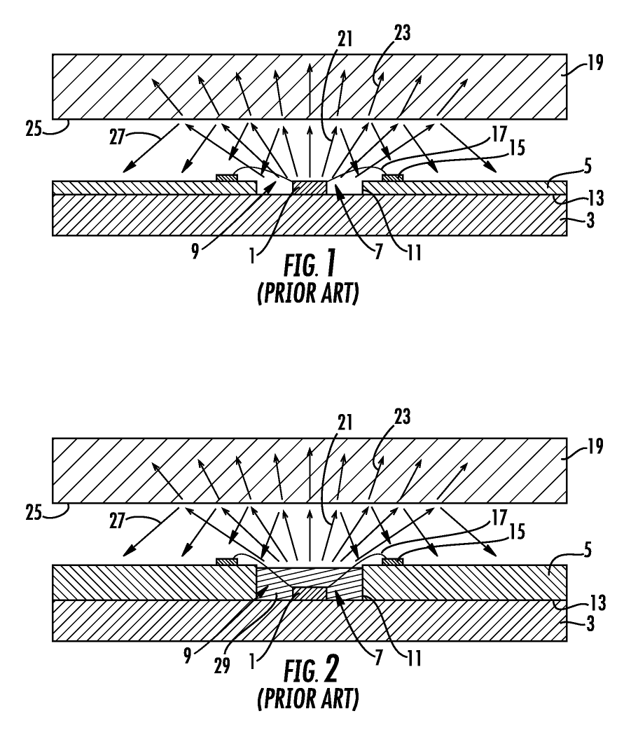

### DETAILED DESCRIPTION

The present disclosure now will be described more fully with reference to the accompanying drawings, in which some, but not all embodiments of the disclosure are shown. This disclosure may be embodied in many different forms and should not be construed as limited to the embodiments set forth; rather, these example embodiments are provided so that this disclosure will be thorough and complete, and will fully convey the scope of the disclosure to those skilled in the art. Like numbers refer to like elements throughout.

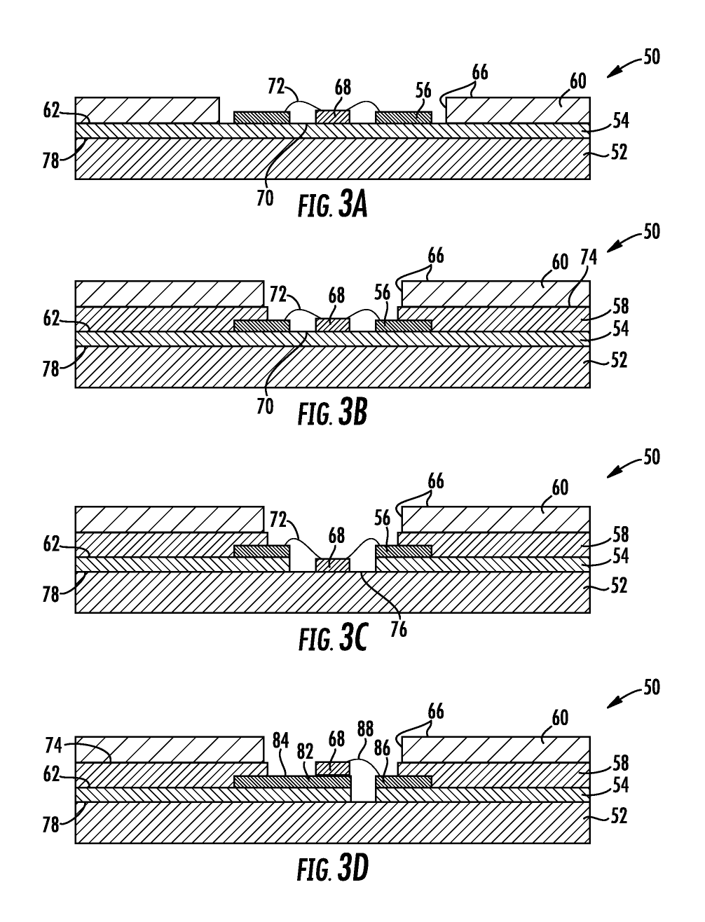

FIGS. 3a-d depict an LED device 50 mounted on a circuit board according to some example embodiments of the present invention. In some example embodiments, the circuit board is a metal core printed circuit board (MCPCB).

In the example embodiment of FIG. 3a, the LED device 50 comprises a substrate 52. In some example embodiments, the substrate 52 is made of a material with high thermal conductivity. In some example embodiments, the substrate 52 is made of a metal, such as aluminum, copper, gold, silver, tungsten, zirconium, or zinc, or an alloy, such as aluminum 2024, aluminum 5052, aluminum 6061, aluminum 7075, aluminum A356, brass yellow, brass red, copper alloy 11000, or a combination thereof. In some example embodiments, the substrate 52 is made of ceramic, such as aluminum nitride, silicon carbide, alumina, or silicon nitride.

In the example embodiment of FIG. 3a, a first dielectric layer 54 is arranged on top of the substrate 52. In some example embodiments, the first dielectric layer 54 is made of such electrically insulating materials as plastic, glass, ceramic, Pre-Preg (glass fiber), fiber, carbon fiber/tube, clad or combination thereof.

In the example embodiment of FIG. 3a, electrode pads and circuit traces 56 are positioned on top of the first dielectric layer 54. In some example embodiments, the electrode pads and circuit traces 56 are made of a metal, such as aluminum, copper, gold, silver, and conductive inks such as gold, copper, silver particles doped epoxy or a combination thereof.

In the example embodiment of FIG. 3a, the LED device 50 also comprises a reflective layer 60 arranged on top of the first dielectric layer 54. In some example embodiments, the reflective layer 60 is a polished metal layer. In some example embodiment, the reflective layer 60 is made of a metal, such as aluminum, silver, gold, titanium, copper, nickel, chrome or an alloy, or a combination thereof or other suitable material capable of providing a reflective surface.

In some example embodiments, the reflective layer 60 is covered with a reflective coating 66. The reflective coating 66 can be silver, aluminum, nickel, chrome, aluminum alloy, combinations thereof or other suitable material capable of providing a reflective surface.

In some example embodiments, the reflective layer 60 is a layer of non-metal material covered with a reflective coating 66. Examples of suitable non-metal materials include ceramic, pre-impregnated composite fiber (“pre-preg”), glass, plastic, and other suitable materials.

In some example embodiments, the reflective layer 60 is a reflective coating deposited directly on the top surface of the circuit board.

In some example embodiments, the reflective layer 60 is attached to the first dielectric layer 54 by an adhesive. In other example embodiments, the reflective layer 60 is sprayed or otherwise deposited on the top surface 62 of the first dielectric layer 60.

In some embodiments, the reflective layer 60 only covers the portions of the top surface 62 of the first dielectric layer 54 that are not in contact with the electrode pads and circuit traces 56. In instances in which the reflective layer 60 is a conductor, the reflective layer 60 will not be in contact with the electrode pads and circuit traces 56 to prevent short-circuiting the LED device 50.

In the example embodiment of FIG. 3a, a portion 70 of the top surface 62 of the first dielectric layer 54 is not covered by the reflective layer 60 or the electrode pads and circuit traces 56, and is thus open. In this example embodiment, an LED die 68 is arranged on the open portion 70 of the top surface 62. This arrangement allows rays of light emitted by the LED die 68 to avoid being blocked by the reflective layer 60 and be free to reach the waveguide (not shown). The LED die 68 is connected to the electrode pads and circuit leads 56 by wires 72.

In some example embodiments, the LED die 68 of the LED device 50 is selected from the group comprising a blue LED, white LED, and UV LED. In some example embodiments, the LED die 68 is covered with phosphor. In some example embodiments, the LED die 68 has both a cathode and an anode on the same plane. In other example embodiments, electrodes of the LED die 68 are on different planes. In other example embodiments, one of the electrodes is on the bottom of the LED die and the other electrode is on top of the LED die. However, example embodiments of the present invention are not limited to a specific type or configuration of the LED die.

In the example embodiment of FIG. 3b, a second dielectric layer 58 is arranged on the top surface 62 of the first dielectric layer 54 between the first dielectric layer 54 and the reflective layer 60. The second dielectric layer 58 at least partially covers the electrode pads and circuit traces 56. As a result, at least a portion of the electrode pads and circuit traces 56 are sandwiched between the first dielectric layer 54 and the second dielectric layer 58. As a result, parts of the substrate covered by both the electrode pads and circuit traces 56 and the second dielectric layer 58 can also be covered by the reflective layer 60. The increase of the area covered by the reflective layer improves reflectivity of the device 50 and thereby its brightness efficiency.

In some example embodiments, the reflective layer 60 at least partially covers the top surface 74 of the second dielectric layer 58. In some example embodiments, the reflective layer 60 entirely covers the top surface 74 of the second dielectric layer 58.

In the example embodiment of FIG. 3b, the second dielectric layer 58 does not cover at least part of the portion 70 of the top surface 62 of the first dielectric layer 54. The LED die 68 is positioned in the portion of the top surface 68 not covered by either the second dielectric layer 58 or the reflective layer 60. As a result, rays emitted by the LED die 68 are not obstructed by the second dielectric layer 58 or the reflective layer 60. As in the example embodiment of FIG. 3a, here the LED die 68 is also connected to the electrode pads and circuit leads 56 by wires 72.

In the example embodiment of FIG. 3c, a portion of the top surface 78 of the substrate 52 that is not covered by the first dielectric layer 54, the second dielectric layer 58 or the reflective layer 60 defines a substrate open top surface 76. In this example embodiment, the LED die 68 is positioned on the substrate open top surface 76. As a result, rays emitted by the LED die 68 are not obstructed by the first dielectric layer 54, the second dielectric layer 58 or the reflective layer 60. Additionally, the direct contact between the LED die 68 and the substrate 52 enhances temperature dissipation from the LED die 68, which improves its performance.

In the example embodiment of FIG. 3d, the LED die 78 has one of its electrodes on the bottom of the LED die 80 and the other of its electrodes on the top of the LED die 80. In this example embodiment, a suitable portion 84 of the top surface of the electrode pad 82 is not covered by the second dielectric layer 58 and the reflective layer 60. The LED die 80 is arranged on the open portion 84 of the electrode 82. The second electrode of the LED die 80 is connected to the electrode pads and circuit traces 86 by a wire 88.

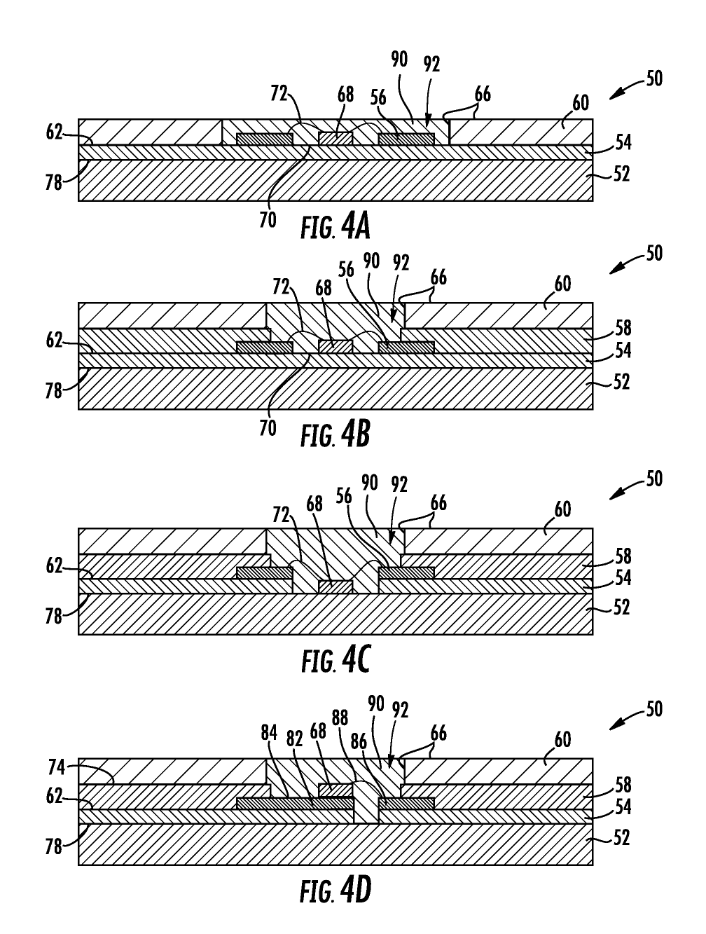

FIGS. 4a-d depict example embodiments of the LED device 50 with phosphor 90 filling a pocket 92 where the LED die 68, 80 is located. The pocket 92 is formed by an open surface of the layer carrying the LED die 68, 80 and the walls of the openings in the other suitable layers. The pocket 92 is deep enough for the LED die 68, 80 to be completely covered with phosphor.

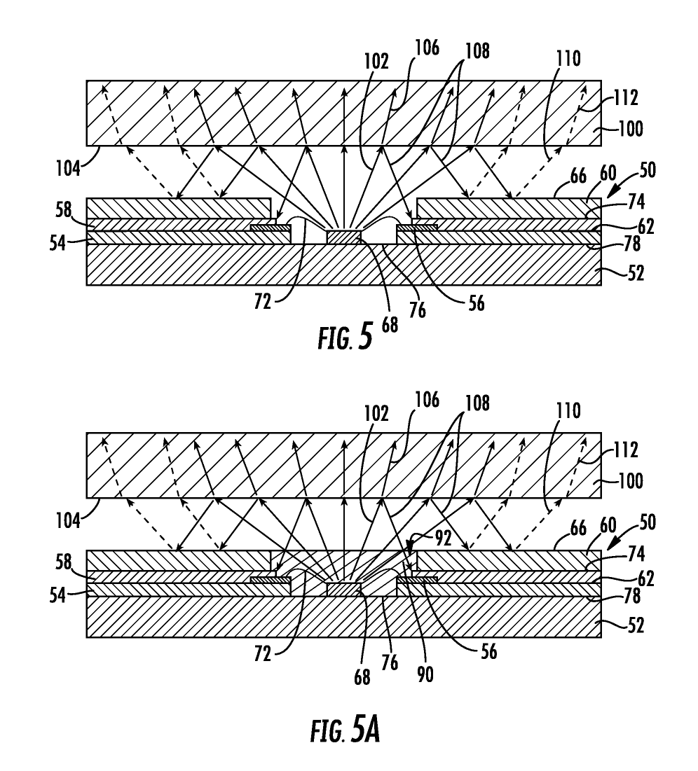

FIG. 5 depicts an exemplary embodiment of the LED device 50 with a waveguide 100 to which rays 102 emitted by the LED die 68 travel. When the emitted rays 102 reach the surface 104 of the waveguide 100, a portion 106 of the light propagates through the waveguide material. However, the rest of the light reflects off the surface 104 of the waveguide 100. The reflected light 108 travels back towards the LED device 50. In an instance in which the reflected light 108 hits the reflective layer 60 or the reflective coating 66, at least a portion of this reflected light 108 is reflected for the second time, this time off the reflective layer 60 or the reflective coating 66. At least a portion of the twice-reflected light 110 travels to the surface 104 of the waveguide 100, and at least a portion 112 of the twice-reflected light 110 propagates through the waveguide 100. As a result, the reflective layer 60 allows the portion of the LED-emitted light 112 to be recycled and contribute to the efficiency of the LED die 68.

FIG. 5A depicts an exemplary embodiment of the LED device 50 having phosphor 90 covering the LED die 68 in the form of a UV LED. As in the above example, the twice-reflected rays 110 travel to the surface 104 of the waveguide 100 and contribute to the light efficiency of the respective LED die 68.

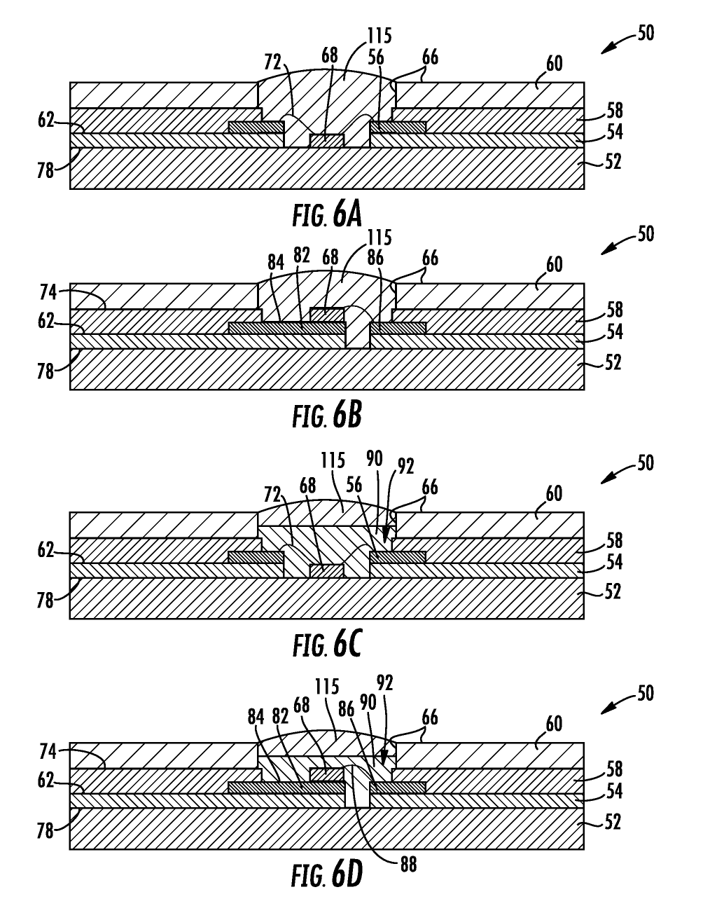

FIGS. 6a-d depict example embodiments of the LED device 50 with a protective layer 115. In some example embodiments, after the LED die 68 is mounted on the circuit board, the LED device 50 is potted, i.e. a protective layer 115 is applied to the LED device 50 covering the LED die 68. This protective layer 115 is usually a plastic shell, such as a cured epoxy drop. In some example embodiments, the protective layer 115 comprises silicone, PMMA (polymethyl methacrylate, a.k.a. Acrylic), PC (Polycarbonate), and Glass lenses In some example embodiments, the protective layer 115 is clear to thereby allow propagation of light emitted by the LED die without changing its wavelength. In other example embodiments, the protective layer 115 is colored to thereby provide a desired change to the wavelength composition of the LED die emitted light.

In some example embodiments, the protective layer 115 also serves as a diffusing optical lens to thereby allow the propagation of light from the light cone at a much higher angle of incidence than otherwise possible by the bare LED die 68 alone.

FIGS. 7-11 show some of the steps in a process of assembling an LED device 50 according to example embodiments of the present invention. Side views are marked (a) and top views are marked (b).

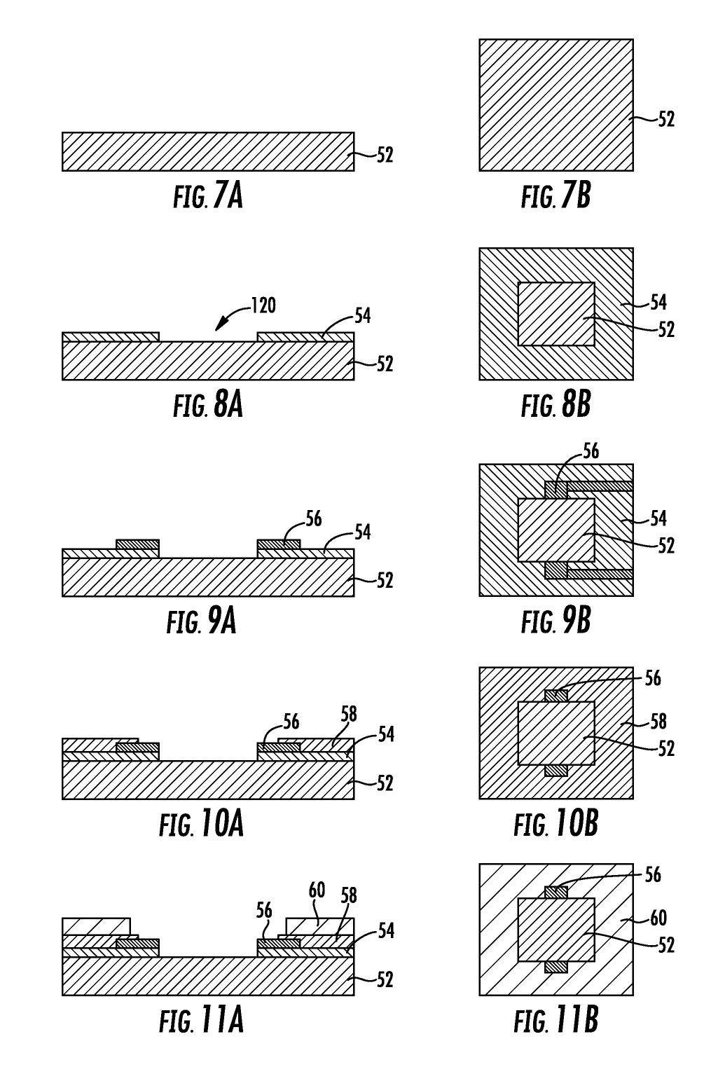

As shown in FIG. 7, the substrate 52 is obtained. Then, the first dielectric layer 54 is arranged on top of the substrate 52 (see FIG. 8). In this embodiment, the first dielectric layer 54 has an opening 120. The walls of the opening 120 and the substrate open top surface 76 form the pocket 92. FIG. 9 shows the electrode pads and circuit traces 56 being arranged over the first dielectric layer 54. Next, the second dielectric layer 58 is deposited over the top surface 62 of the first supporting layer 54 (see FIG. 10). The second dielectric layer 58 also at least partially covers the electrode pads and the circuit traces 56. FIG. 11 shows the step of depositing the reflective layer 60 over the second dielectric layer 58.

Many modifications and other example embodiments set forth herein will come to mind to one skilled in the art to which these example embodiments pertain having the benefit of the teachings presented in the foregoing descriptions and the associated drawings. Therefore, it is to be understood that the embodiments are not to be limited to the specific ones disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims. Although specific terms are employed herein, they are used in a generic and descriptive sense only and not for purposes of limitation.

That which is claimed:

1. A light emitting diode (LED) device comprising:
a substrate having a substrate top surface;
a first dielectric layer arranged on the substrate top surface and having a first dielectric layer top surface, the first dielectric layer covering at least a portion of the substrate top surface;
electrode pads and circuit traces arranged on the first dielectric layer top surface;
an LED die arranged on the first dielectric layer top surface; and
a reflective layer arranged over the first dielectric layer so that the reflective layer is not in contact with the electrode pads and circuit traces and the LED die; the reflective layer covers at least a portion of the first dielectric layer top surface.

2. The LED device of claim 1 further comprising:
a second dielectric layer at least partially covering the first dielectric layer top surface and positioned at least partially between the first dielectric layer and the reflective layer, and between the electrode pads and circuit traces and the reflective layer,
wherein the second dielectric layer has a second dielectric layer top surface at least partially covered by the reflective layer.

3. The LED device of claim 1 wherein the reflective layer has a reflective layer top surface that is coated with a reflective coating.

4. The LED device of claim 1 wherein the reflective layer is a reflective coating.

5. The LED device of claim 1 wherein the reflective layer has a reflective layer top surface that is polished.

6. The LED device of claim 1 wherein the LED die is covered by phosphor.

7. The LED device of claim 1 wherein the LED die is covered by a protective layer.

8. A light emitting diode (LED) device comprising:
a first dielectric layer arranged on the substrate top surface, the first dielectric layer having a first dielectric layer top surface, a first dielectric layer bottom surface and walls substantially perpendicular to the first dielectric layer top surface and the first dielectric layer bottom surface, the walls defining an opening in the first dielectric layer, the first dielectric layer covers;
a substrate having a substrate top surface on which the first dielectric layer is arranged and a portion of which the first dielectric layer covers, the substrate top surface comprising a substrate open top surface formed by a portion of the substrate top surface not covered by the first dielectric layer and the perimeter of the opening in contact with the substrate top surface;
electrode pads and circuit traces arranged on the first dielectric layer top surface;
an LED die arranged on the substrate open top surface; and
a reflective layer arranged over the first dielectric layer such that the reflective layer at least partially covers the dielectric layer top surface but does not cover the substrate open top surface.

9. The LED device of claim 8 further comprising:
a second dielectric layer at least partially covering the first dielectric layer and positioned at least partially between the first dielectric layer and the reflective layer, and between the electrode pads and circuit traces and the reflective layer,
wherein the second dielectric layer is arranged such that the second dielectric layer does not cover the substrate open top surface, and
wherein the second dielectric layer has a second dielectric layer top surface at least partially covered by the reflective layer.

10. The LED device of claim 8 wherein the reflective layer has a reflective layer top surface that is coated with a reflective coating.

13. The LED device of claim 8 wherein the reflective layer is a reflective coating.

14. The LED device of claim 8 wherein the reflective layer has a reflective layer top surface that is polished.

15. The LED device of claim 8 wherein the LED die is covered by phosphor.

16. The LED device of claim 8 wherein the LED die is covered by a protective layer.

17. A light emitting diode (LED) device comprising:
a substrate having a substrate top surface;
a first dielectric layer arranged on the substrate top surface and having a first dielectric layer top surface;
electrode pads and circuit traces arranged on the first dielectric layer top surface; and
an LED die arranged on the first dielectric layer top surface,
wherein the first dielectric layer is arranged such that the first dielectric layer is not in contact with the electrode pads and circuit traces and the LED die, and
wherein the first dielectric layer top surface is at least partially polished.

18. A method of forming a light emitting diode (LED) device comprising:
providing a substrate having a top surface;
arranging a first dielectric layer over the substrate such that the first dielectric layer covers at least a portion of the substrate top surface, the first dielectric layer having a first dielectric layer top surface;
arranging electrode pads and circuit traces over the first dielectric layer top surface;
arranging an LED die over the first dielectric layer top surface; and
arranging a reflective layer over the first dielectric layer such that the reflective layer is not in contact with the electrode pads and circuit traces and the LED die and such that the reflective layer covers at least a portion of the first dielectric layer top surface.

19. The method of claim 18 further comprising:
arranging a second dielectric layer having a second dielectric layer top surface between the first dielectric layer and the reflective layer, and between the electrode pads and circuit traces and the reflective layer, the second dielectric layer being arranged such that the second dielectric layer at least partially covers the first dielectric layer top surface.

20. The method of claim 18 further comprising forming a plurality of LED devices on the same substrate.

21. The method of claim 18 further comprising:
depositing a reflective coating on a top surface of the reflective layer.

22. The method of claim 18 further comprising:
covering the LED die with phosphor.

23. The method of claim 18 further comprising:
depositing a protective layer over the LED die.

24. A method of forming a light emitting diode (LED) device comprising:
providing a first dielectric layer having a first dielectric layer top surface, a first dielectric layer bottom surface and walls substantially perpendicular to the first dielectric layer top surface and the first dielectric layer bottom surface, the walls defining an opening in the first dielectric layer;
arranging the first dielectric layer over a substrate having a top surface, the first dielectric layer being arranged such that the first dielectric layer covers at least a portion of the substrate top surface, the substrate top surface comprising a substrate open top surface formed by a portion of the substrate top surface not covered by the first dielectric layer and the perimeter of the opening in contact with the substrate top surface;
arranging electrode pads and circuit traces over the first dielectric layer top surface;
arranging an LED die on the substrate open top surface; and
arranging a reflective layer over the first dielectric layer such that the reflective layer at least partially covers the dielectric layer top surface but does not cover the substrate open top surface.

25. The method of claim 24 further comprising:
arranging a second dielectric layer between the first dielectric layer and the reflective layer, and between the electrode pads and circuit traces and the reflective layer,
wherein the second dielectric layer is arranged such that the second dielectric layer at least partially covers the first dielectric layer top surface but does not cover the substrate open top surface.

26. The method of claim 24 further comprising forming a plurality of LED devices on the same substrate.

27. The method of claim 24 further comprising:
depositing a reflective coating on a top surface of the reflective layer.

28. The method of claim 24 further comprising:
covering the LED die with phosphor.

29. The method of claim 24 further comprising:
depositing a protective layer over the LED die.
